(19) United States
(12) Patent Application Publication
(10) Pub. No.: US 2003/0046625 A1
(43) Pub. Date: Mar. 6, 2003

(54) Method and apparatus for efficient control of multiple tap controllers

(76) Inventors: Sankaran M. Menon, Austin, TX (US); Eduardo J. Rodriguez, Phoenix, AZ (US); Terry R. Altmayer, Monument, CO (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/944,263

(22) Filed: Aug. 30, 2001

(51) Int. Cl. G01R 31/28

(52) U.S. Cl. 714/727

(57) ABSTRACT

A system to select a first and second test access port controller in response to a mode of operation.

### BACKGROUND OF THE CLAIMED SUBJECT MATTER

1. Field of the Claimed Subject Matter

The present claimed subject matter relates to design for test improvements, and specifically to a method and apparatus for an efficient control of multiple test access port (TAP) controllers.

2. Description of the Related Art

As the technology for manufacturing integrated circuits advances, more logic functions are included in a single integrated circuit device or a system on a chip (SoC). Modem integrated circuit (IC) devices include large numbers of gates on a single semiconductor chip, with these gates interconnected so as to perform multiple and complex functions. The fabrication of an IC incorporating such Very Large Scale Integration (VLSI) must be error free, as a manufacturing defect may prevent the IC from performing all of the functions that an IC or SoC is designed to perform. Such demands require verification of the design of the IC or SoC and also various types of electrical testing after the IC or SoC is manufactured.

However, as the complexity of the ICs and SoCs increase, so does the cost and complexity of verifying and electrically testing the individual IC or multiple ICs in a system, such as a system on a chip (SoC). Testing and manufacturing costs and design complexity increase dramatically because of the increasing number of functional pins on the integrated devices. One way to address this problem is through design for test (DFT). Typically, various test patterns are loaded into the IC or SoC for testing, debug, and emulation analysis via the TAP. Also, the values of various logic nodes within the IC or SoC are unloaded for further analysis via the TAP. A TAP is a plurality of pins on the IC or SoC to interface with an external host or test system. A Joint Test Action Group (JTAG) and a standard of Institute of Electrical and Electronics Engineers (I.E.E.E) 1149.1 define the TAP pins.

A typical design for multiple TAP controllers is illustrated in FIG. 1. The design illustrates a plurality of defined pins to serve the function of data input, data output, clock, and reset. For example, TDI pin is a test data in pin that allows for values to be loaded into the multiple cores via a host or test system. Also, TDO pin is a test data out pin that allows for values from within the multiple cores to be unloaded to a host or test system for further analysis. The TCK pin is a test clock to enable the various logic storage elements, such as flip-flops and latches, to propagate the values within the core. Also, the TMS pin is a test mode select pin. Finally, TRST is the test reset pin.

The prior art design in FIG. 1 has various limitations. First, it violates the I.E.E.E 1149.1 standard because it allows for control of multiple TAP controllers at the SoC level. In contrast, the I.E.E.E 1149.1 standard allows for control of a single TAP controller at the SoC level. Also, the prior art design of FIG. 1 is an inefficient utilization of pins at the SoC level and increases the difficulty of routing the various TMS, TCK, and TRST signals to the multiple cores. Furthermore, the prior art design is incompatible with various commercial software tools that are utilized for verification and for generating Very high speed integrated circuit Hardware Description Language (VHDL) and Register Transfer Level (RTL) designs because the prior art design violates the I.E.E.E 1149.1 standard. Some examples of the commercial software are BSD Architect from Mentor Graphics® and TapDance from Bell Labs®.

### BRIEF DESCRIPTION OF THE SEVERAL VIEWS OF THE DRAWINGS

The claimed subject matter is particularly pointed out and distinctly claimed in the concluding portion of the specification. The claimed subject matter, however, both as to organization and method of operation, together with objects, features, and advantages thereof, may best be understood by reference to the following detailed description when read with the accompanying drawings in which:

FIG. 1 illustrates prior art.

FIG. 2 illustrates a block diagram utilized by one embodiment.

FIG. 3 illustrates a block diagram utilized by one embodiment.

### DETAILED DESCRIPTION OF THE CLAIMED SUBJECT MATTER

A method and apparatus for an efficient control of multiple test access port (TAP) controllers are described. In the following description, for purposes of explanation, numerous details are set forth in order to provide a thorough understanding of the claimed subject matter. However, it will be apparent to one skilled in the art that these specific details are not required in order to practice the present invention.

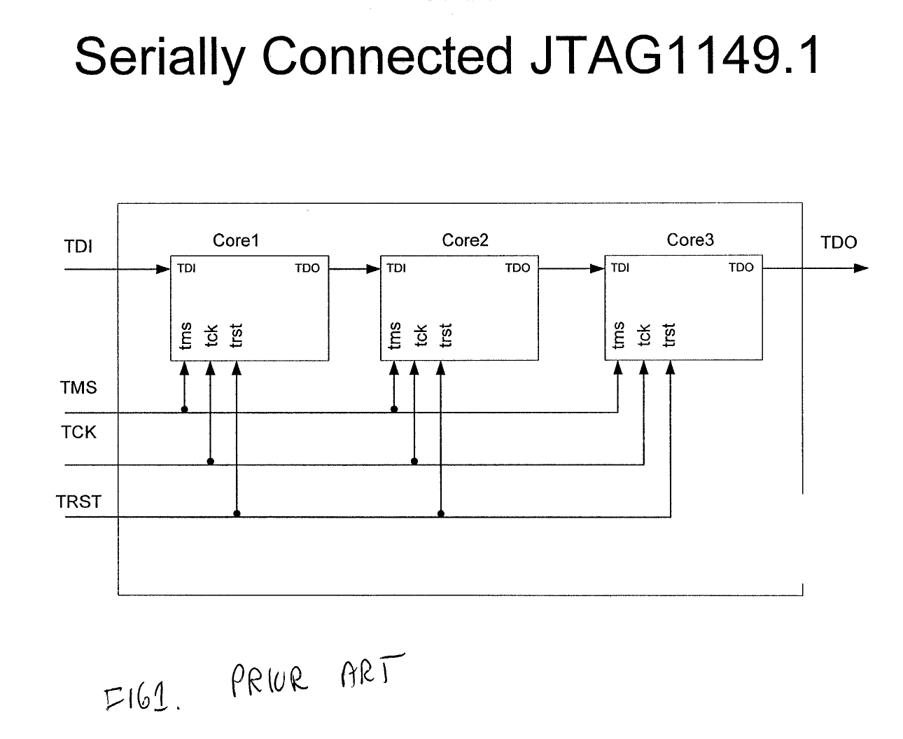

An area of current technological development relates to minimizing the number of pins for controlling multiple TAPs to support multiple modes of operation for a SoC or integrated device. As previously described, the prior art design of FIG. 1 has multiple limitations such as inefficient use of pins, increased routing, and incompatibility with commercial software for verification and generation of VHDL and RTL. Thus, implementing a more efficient method and apparatus of controlling multiple TAPs to support multiple modes of operation is desirable.

In one aspect, the claimed subject matter utilizes a minimal number of pins at the SoC level to support multiple modes of operation such as debug, emulation, test, and functional modes for the SoC or the integrated device. In another aspect, the claimed subject matter enables the use of commercial software such as BSD Architect and TapDance because the claimed subject matter complies with the I.E.E.E 1149.1 standard. In yet another aspect, the claimed subject matter allows for increased design and test flexibility by allowing one to select one TAP for one mode of operation, while choosing another TAP for another mode of operation.

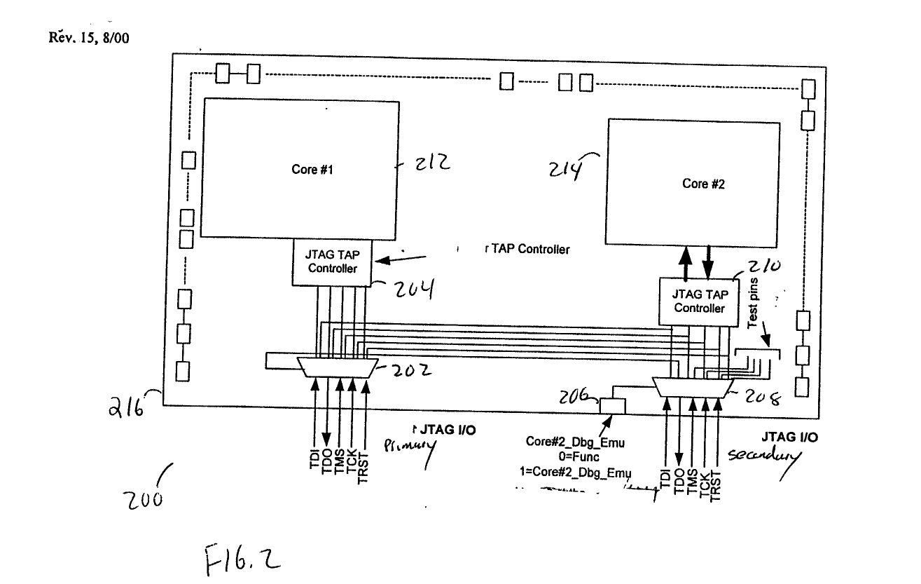

FIG. 2 illustrates a block diagram 200 utilized by one embodiment. In one embodiment, the block diagram is a SoC 216 with a plurality of cores and a plurality of TAP controllers. The block diagram 200 comprises, but is not limited to, a first core 212, a second core 214, a first TAP controller 204, a second TAP controller 210, a first multiplexer 202, a second multiplexer 208, a select pin 206, and a plurality of pins 220. The first and second multiplexer receive the JTAG 1149.1 compliant signals, TDI, TDO, TMS, TCK, TRST via pins from the SoC package. In one embodiment, the control of the first and second TAP controller 204 and 210 is in response to the value of the select pin 206.

The block diagram 200 allows for increased design and test flexibility because of supporting multiple modes of operation of the SoC. Depending on the mode of operation for the SoC, one or both TAP controllers are required. For example, for a mode of operation such as debug or emulation there is a need for simultaneous access to both TAP controllers. In contrast, for a mode of operation to test one of the cores there is only a need for access to one of the TAP controllers.

One example is a mode of operation for testing core 212. First, the TAP Controller 204 and multiplexer 202 receive the JTAG 1149.1 compliant signals, TDI, TDO, TMS, TCK, TRST. Meanwhile, TAP controller 210 and multiplexer 208 are not needed to test core 212. Thus, the pins 220 coupled to multiplexer 208 are not needed for the JTAG signals and could be utilized for other functional purposes. Therefore, in one embodiment the value of the select pin 206 is set to a binary zero value to allow for the multiplexer 208 to use pins 220 for functional and/or test purposes rather than being coupled to TAP controller 210 for a JTAG testing purpose.

In one aspect, the pins coupled to multiplexer 208 support JTAG signals for one mode of operation, such as, debug or emulation, while supporting functional purposes for another mode of operation, such as, testing core 212, or functional inputs for core 214, or other operational modes of operation. In contrast, for another mode of operation such as debug or emulation, both TAP controllers 204 and 210 are needed. Thus, the select pin 206 is set to a binary one value to allow the pins at the SoC level and multiplexer 208 to receive the JTAG signals. Therefore, in one aspect the claimed subject matter allows for increased efficiency and flexibility because of minimal use of pins and allowing for the pins at the SoC level to be used for multiple purposes. The minimal use of pins increases efficiency by reducing manufacturing cost and test costs by reducing test complexity, while still supporting the necessary design and test requirements of testing multiple cores. Also, the claimed subject matter is JTAG 1149.1 compliant since there is only TAP controller in use at the SoC level.

Another example is a mode of operation to test core 214. In one embodiment, the TDI pin coupled to the multiplexer 208 enables the testing of core 214 by instructing the multiplexer 202 to forward the JTAG signals from multiplexer 202 to TAP controller 210. However, the claimed subject matter is not limited to the TDI pin controlling multiplexer 202, rather, the claimed subject matter is capable of supporting any of the JTAG signals or any other pin to enable multiplexer 202. Thus, the pins 220 could be used for functional purposes and increase the flexibility and efficiency of the block diagram by allowing the SoC to have more features because of the ability to allow for pins 220 to have multiple uses. As one example, the pins 220 could be used for to receive more address bits to support a larger cache memory within one of the cores or coupled to one of the cores. Another example, the pins 220 could be used for increased bandwidth to receive more data bits. In yet another example, the pins 220 may be used for enhanced test-modes for performing custom tests on core 214 while the tap controller 204 is used to test the core 212. Another example is the pins 220 may be used as personality pins, which configure the device to respond to a specific predetermined address or select a predetermined mode of operation. Also, the pins 220 may be used to observe and access various internal signals in the cores for debugging, test, or emulation purposes.

In one embodiment, the cores are multiprocessors. In another embodiment, the cores are micro-controllers. In yet another embodiment, the cores are application specific integrated circuits (ASICs). One skilled in the art appreciates modifications. For example, the block diagram 200 could have more than two cores. Also, the cores could operate independently of each other. In another embodiment, the cores could be interchanged, for example, one core may be an ASIC and the other core could be a microprocessor.

In one embodiment, the SoC has various modes of operations that determine the number of TAP controllers needed for each mode. For example, as previously discussed, when the mode of operation is to test one of the cores only one TAP controller was needed. In contrast, when the mode of operation is debug or emulation, simultaneous access of both TAP controllers is needed and the multiplexer 208 forwards the JTAG signals to TAP controller 210.

One skilled in the art appreciates the variety of possible modes of operations and the ability for the block diagram to handle a variety of modes of operations. As previously discussed, the block diagram supports various modes of operations such as testing only one core, debug, or emulation. For example, testing one of the cores could refer to isolating one of the cores and sending various initialization signals, or functional vectors, or automatic test pattern generated (ATPG) vectors via one of the TAP controllers 204 or 210. Also, for a mode of operation of debug this could refer to a manufacturing level test of more than one core or a field test of more than one core. Finally, for a mode of operation of emulation, this could refer to testing the SoC when placed into a product and monitoring the signal activity at the interface between the SoC and the product. Also, the block diagram 200 could support more modes of operation by increasing the number of select pins or control signals or with a decoder.

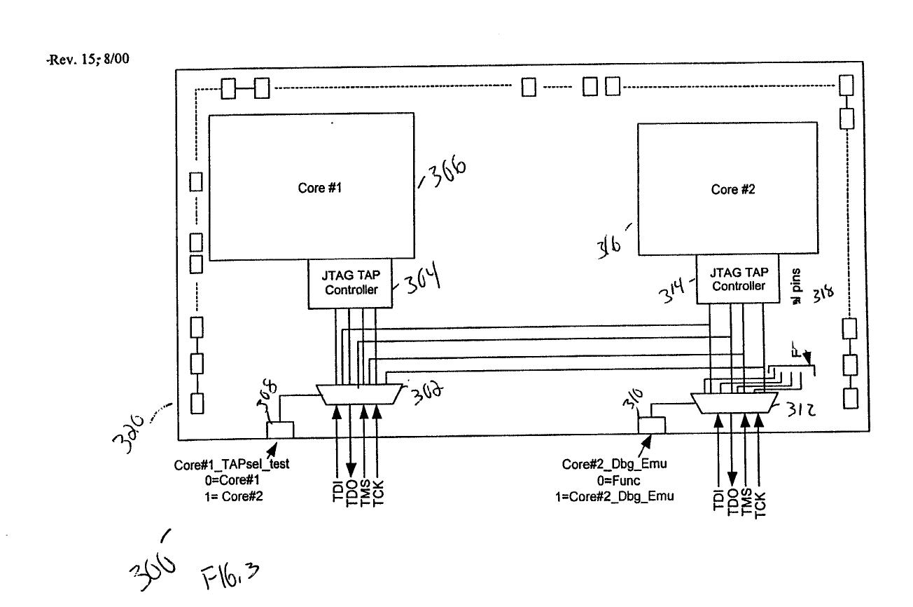

FIG. 3 illustrates a block diagram 300 utilized by one embodiment. In one embodiment, the block diagram is a SoC 320 with a plurality of cores and a plurality of TAP controllers. The block diagram 300 comprises, but is not limited to, a first core 306, a second core 316, a first TAP controller 304, a second TAP controller 314, a first multiplexer 302, and a second multiplexer 312, a first select pin 308, a second select pin 310, and a plurality of pins 318. The first and second multiplexers receive the JTAG 1149.1 compliant signals, TDI, TDO, TMS, TCK, and TRST via pins from the SoC package. In one embodiment, the control of the first and second TAP controller 304 and 314 is in response to the value of the select pins 308 and 310.

The block diagram 300 allows for increased design and test flexibility because of supporting multiple modes of operation of the SoC. Depending on the mode of operation for the SoC, one or both TAP controllers are required. For example, for a mode of operation such as debug or emulation there is a need for simultaneous access to both TAP controllers. In contrast, for a mode of operation to test one of the cores there is only a need for access to one of the TAP controllers.

One example is a mode of operation for testing the first core 306. First, the TAP Controller 304 and the first multiplexer 302 receive the JTAG 1149.1 compliant signals, TDI, TDO, TMS, TCK, TRST. Also, the first select pin 308 has a binary value of “0” in order to select the first core 306 for testing. Meanwhile, TAP controller 314 and the second multiplexer 312 are not needed to test the first core 306. Also, the second select pin 310 has a binary value of “0” to enable the pins 318 coupled to multiplexer 312 to be utilized for other functional purposes because they are not needed for the JTAG signals. Therefore, in one embodiment the value of the first select pin and the second select pin are set to a binary zero value to allow for the multiplexer 312 to use pins 318 for functional purposes rather than being coupled to TAP controller 314 for a JTAG testing purpose.

In one aspect, the pins 318 coupled to multiplexer 312 support JTAG signals for one mode of operation such as debug or emulation, while supporting functional purposes for another mode of operation such as testing the first core 306. In contrast, for another mode of operation such as debug or emulation, both TAP controllers 304 and 314 are needed. Thus, the second select pin is set to a binary one value to allow the pins at the SoC level and multiplexer 312 to receive the JTAG signals. Therefore, in one aspect the claimed subject matter allows for increased efficiency and flexibility because of minimal use of pins and allowing for the pins at the SoC level to be used for multiple purposes. Also, the claimed subject matter is JTAG 1149.1 compliant since there is only TAP controller in use at the SoC level.

Another example is to test the second core 316. In one embodiment, the first select pin is set to a binary one value enables the testing of the second core 316 by instructing the multiplexer 302 to forward the JTAG signals from multiplexer 302 to TAP controller 314. Thus, the pins 318 could be used for functional purposes and increase the flexibility and efficiency of the block diagram by allowing the SoC to have more features because of the ability to allow for pins to have multiple uses. For example, the pins 318 could be used for to receive more address bits to support a larger cache memory within one of the cores or coupled to one of the cores. Also, the pins 318 could be used for increased bandwidth to receive more data bits. In yet another example, the pins 318 may be used for enhanced test-modes for performing custom tests on core 316 while the tap controller 304 is used to test the core 306. Another example is the pins 318 may be used as personality pins, which configure the device to respond to a specific predetermined address or select a predetermined mode of operation. Also, the pins 318 may be used to observe and access various internal signals in the cores for debugging, test, or emulation purposes.

In one embodiment, the cores are multiprocessors. In another embodiment, the cores are micro-controllers. In yet another embodiment, the cores are application specific integrated circuits (ASICs). One skilled in the art appreciates modifications. For example, the block diagram 300 could have more than two cores. Also, the cores could operate independently of each other. In another embodiment, the cores could be interchanged, for example, one core may be an ASIC and the other core could be a microprocessor.

In one embodiment, the SoC has various modes of operations that determine the number of TAP controllers needed for each mode. For example, as previously discussed, when the mode of operation is to test one of the cores only TAP controller was needed. In contrast, when the mode of operation is debug or emulation, simultaneous access of both TAP controllers is needed and the multiplexer 312 forwards the JTAG signals to TAP controller 314.

One skilled in the art appreciates the variety of possible modes of operations and the ability for the block diagram to handle a variety of modes of operations. As previously discussed, the block diagram supports various modes of operations such as testing only one core, debug, or emulation. For example, testing one of the cores could refer to isolating one of the cores and sending various initialization signals, or functional vectors, or automatic test pattern generated (ATPG) vectors via one of the TAP controllers 304 or 314. Also, for a mode of operation of debug this could refer to a manufacturing level test of more than one core or a field test of more than one core. Finally, for a mode of operation of emulation, this could refer to testing the SoC when placed into a product and monitoring the signal activity at the interface between the SoC and the product.

While the claimed subject matter has been described with reference to specific modes and embodiments, for ease of explanation and understanding, those skilled in the art will appreciate that the claimed subject matter is not necessarily limited to the particular features shown herein, and that the claimed subject matter may be practiced in a variety of ways that fall under the scope and spirit of this disclosure. The claimed subject matter is, therefore, to be afforded the fullest allowable scope of the claims that follow.

1. A system comprising:
a plurality of cores;
a first test access port controller coupled to at least one core;
a second test access port controller coupled to at least one core; and
a select pin to control the first and second test access port controller to support a plurality of system modes of operation.

2. The system of claim 1 further comprising:
a first multiplexer coupled to the first test access port controller, the second test access port controller, and to a first plurality of Joint Test Action Group (JTAG) signals; and
a second multiplexer coupled to the second test access port controller, a second plurality of Joint Test Action Group signals and to a plurality of pins.

3. The system of claim 1 wherein the system is a system on a chip (SoC).

4. The system of claim 1 wherein the plurality of system modes of operation is at least two of a debug mode, an emulation mode, or a test of at least one of the plurality of cores.

5. The system of claim 2 wherein the second multiplexer forwards the plurality of JTAG signals to the second test access port controller for either a debug mode of operation or an emulation mode of operation.

6. The system of claim 2 wherein the first multiplexer forwards the plurality of JTAG signals to the first test access port controller for either a debug mode of operation, or an emulation mode of operation, or to test one of the cores.

7. The system of claim 2 wherein the second multiplexer does not forward the plurality of JTAG signals to the second test access port controller for the system mode of operation to test one of the plurality of cores, and the plurality of pins coupled to the second multiplexer are utilized for other functional purposes for the system mode of operation to test one of the plurality of cores.

8. A method for controlling test access port controllers comprising:
generating a select signal;
selecting either a first test access port controller or second access port controller for a first mode of operation in response to the select signal; and
selecting both the first test access port controller and second access port controller for a second mode of operation in response to the select signal.

9. The method of claim 8 further comprising:
multiplexing between a plurality of Joint Test Action Group signals and a plurality of pins.

10. The method of claim 8 wherein the select signal comprises either a single pin or a combination of two pins.

11. The method of claim 8 wherein the first mode of operation is testing a single core.

12. The method of claim 8 wherein the second mode of operation is either a debug mode of operation or an emulation mode of operation.

13. The method of claim 9 wherein the multiplexing comprises:
forwarding the Joint Test Action Group signals in response to the second mode of operation; and
forwarding the pins in response to the first mode of operation for other functional uses.

14. A system comprising:
a plurality of cores;
a first multiplexer coupled to a first test access port controller and to at least one core;
a second multiplexer coupled to a second test access port controller and to at least one core;
a first pin to control the first multiplexer; and
a second pin to control the second multiplexer.

15. The system of claim 14 further comprising:
a plurality of Joint Test Action Group signals coupled to the first and second multiplexer; and
a plurality of pins coupled to the second multiplexer.

16. The system of claim 14 wherein the first pin is to select a core for a test mode of operation.

17. The system of claim 14 wherein the second pin is to select either one of a functional mode of operation, or a debug mode of operation, or an emulation mode of operation.

18. The system of claim 15 wherein the second multiplexer forwards the plurality of JTAG signals to the second test access port controller for either a debug mode of operation or an emulation mode of operation.

19. The system of claim 15 wherein the first multiplexer forwards the plurality of JTAG signals to the first test access port controller for either a debug mode of operation, or an emulation mode of operation, or to test one of the cores.

20. The system of claim 14 wherein the second multiplexer does not forward the plurality of JTAG signals to the second test access port controller for a mode of operation to test one of the plurality of cores, and the plurality of pins coupled to the second multiplexer are utilized for other functional purposes for the system mode of operation to test one of the plurality of cores.
